(19) United States
(12) Patent Application Publication
(10) Pub. No.: US 2026/0309880 A1
(43) Pub. Date: Oct. 8, 2026

(54) NEUTRON EVENT RATE DETECTOR

(71) Applicant: Raytheon Company, Arlington, VA (US)

(72) Inventors: Johnny Shing Tung Ng, POTOMAC, MD (US); William A. Squires, Arlington, VA (US); David A. Brennan, MAYNARD, MA (US); James R. Murphy, NEEDHAM, MA (US)

(21) Appl. No.: 19/098,636

(22) Filed: Apr. 2, 2025

(51) Int. Cl. G01T 3/00; G01R 31/303; G01T 7/00

(52) U.S. Cl. CPC G01T 3/00; G01R 31/303; G01T 7/005

(57) ABSTRACT

A system and method for measuring high-flux neutron event rates is described. Microelectronic components including an active device with controller circuitry and a processor with high-speed capabilities are used to detect functional error modes caused by neutron single event effects when neutrons interact with semiconductor structures, generating secondary particles that create charge deposits near active junctions. The detection methodology measures neutron event rates through two independent approaches—event counting and timing analysis—where the system calculates neutron flux by determining error rates and analyzing time distributions between events following exponential behavior, with processing occurring through firmware and software components operating at MHz frequencies that detect, reset, and analyze functional errors.

### GOVERNMENTAL RIGHTS

This application was made with government support. The government has certain rights in the application.

### FIELD

The subject matter disclosed herein relates to neutron detection.

### BACKGROUND

High-flux neutrons are present in various environments including nuclear events, laboratory neutron sources, nuclear reactors, and proton radiotherapy facilities. In environments such as nuclear events, more than a million neutrons can be released in less than a second per centimeter-square unit area. Detecting neutrons presents significant challenges because neutrons are (by definition) neutral particles whose interactions with matter are dominated by relatively rare nuclear processes. Traditional neutron detection methods have relied on specialized sensor materials and custom-designed electronics to process signals. For example, silicon photodiode approaches measure leakage current increases caused by neutron displacement damage, but these methods are highly non-linear with respect to neutron flux and face calibration challenges due to long-term annealing and temperature effects. Other methods of neutron detection are large and bulky, in addition to being expensive. It would be desirable to provide a neutron detector that is relatively inexpensive, compact, and has the ability to monitor high-flux neutrons and provide real-time data for multiple applications.

### BRIEF DESCRIPTION OF THE FIGURES

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIG. 1 illustrates a neutron event rate detector system in accordance with some embodiments.

FIG. 2 shows a method of detecting events according to some embodiments.

FIG. 3 illustrates graphics of the method of FIG. 2 according to some embodiments.

FIG. 4 illustrates a block diagram of an electronic device in accordance with some embodiments.

FIG. 5 illustrates another embodiment of a neutron event detection system.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

As above, neutron detectors have been used in a variety of situations, but have a number of deficiencies. The issues with existing detectors include complexity, cost, and size, and make the use of conventional neutron detectors impracticable for a number of applications. In particular, modern complex devices such as microcontrollers, Field Programmable Gate Arrays (FPGAs), and memory devices are vulnerable to single event effects, where neutrons (high energy or thermal neutrons) can generate secondary byproducts that deposit charge near active junctions. For example, a Boron isotope can capture a thermal neutron and release 2.3 MeV of energy (the Q-value of the process) and may emit an alpha particle of 1.47 MeV. This vulnerability has become increasingly relevant as device feature sizes have decreased. This may result in a logic state change, latchup, or burnout.

While neutron single event effects may be used for detection by counting memory bit errors in Static Random-Access Memory (SRAM) devices, this approach involves reading and writing large memory sections, has high latency, and is susceptible to sudden error bursts that results in non-linear responses to neutron flux. The neutron detector described herein is inexpensive, compact, and has the ability to monitor high-flux neutrons and provide real-time data for multiple applications, including protecting electronics vulnerable to neutron damage, characterizing neutron source production performance, and supporting personnel safety.

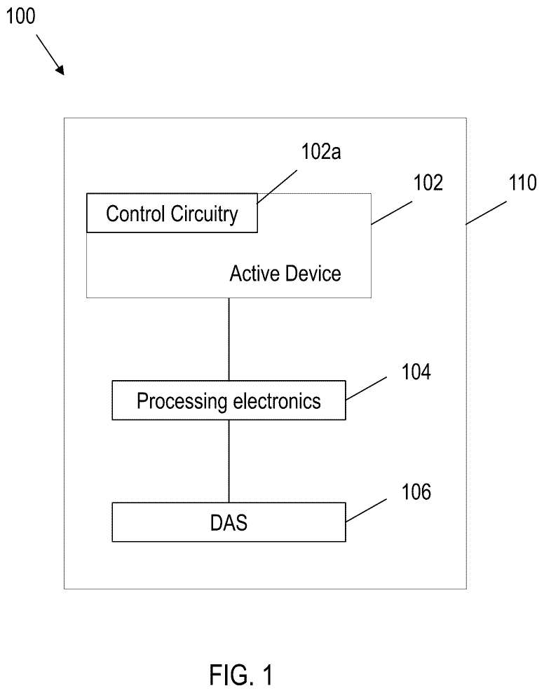

FIG. 1 illustrates a neutron event rate detector (NERD) system in accordance with some embodiments. In some embodiments, a NERD system 100 may include microelectronic components that detect neutron single event effects (nSEEs). The system 100 includes a neutron sensor implemented using an active device 102, processing electronics 104, and a real-time data acquisition system 106. The system 100 may be provided on a printed circuit board (PCB) 110, on which other electronics (e.g., graphics processor) may also be disposed.

For the active device 102 to work as a neutron sensor, the active device 102 is a device that is susceptible to neutron single event effects. The neutron single event effects cause functional interrupts in operations of the active device 102. In particular, the active device 102 may have controller circuitry that can experience single event functional interrupts (SEFI). In addition, the active device 102 may be able to reset and recover without permanent damage, as well as exhibiting a linear response to neutron flux through its error rate. In some embodiments, the active device 102 may be a commercial off-the-shelf (COTS) integrated circuit (IC) device that can interface with the real-time data acquisition system 106. Examples of the active device 102 include, for example, an embedded Multi-Media Card (eMMC) NAND Flash, a microcontroller, a processor, a FPGA, and other complex ICs. As shown, the active device 102 may contain controller circuitry 102a. The active device 102 may be selected for the specific neutron flux environment where the active device 102 is to be used, as different devices may have different cross-sections and sensitivities to neutron events. In some embodiments, the active device 102 may be an electronic device (e.g., NAND flash or other memory device) specifically designed for neutron detection.

The active device 102 may be coupled to processing electronics 104. The processing electronics 104 may include a system on chip that combines a processor plus Field Programmable Gate Array (FPGA). The processing electronics 104 provides the computing infrastructure and high-speed interface capabilities for handling multiple sensors (i.e., multiple active devices 102 if present) and interacting with the real-time data acquisition system 106. The FPGA provides high-speed interface capabilities simultaneously to multiple sensors to achieve redundancy and increased sensitivity, while delivering real-time response and low latency data processing.

The real-time data acquisition system 106 is used to detect and analyze error events. In some examples, the analysis methodology may employ one or more statistical approaches for error rate calculation. In particular, the real-time data acquisition system 106 refers to the firmware and software implementation that runs on the hardware provided by the processing electronics 104 to perform the actual detection and analysis functions, including continuously interrogating the neutron sensor, detecting and resetting functional interrupts, counting SEFI events, measuring time between events, and calculating neutron flux using calibration parameters. That is, the processing electronics 104 provide the platform and capabilities, while the data acquisition system 106 provides the specific implementation and methodology for detecting and analyzing the neutron events.

The control circuitry 102a may include circuitry that provides internal control of the active device 102. The active device 102 may also include one or more input and output interfaces and power management circuitry. The active device 102 may include processor core designs for complex calculations and data manipulations, and processor cache designs for storing data and instructions, as well as a dedicated memory unit for massive storage.

The system 100 may include a computer system or computing device that provides operation and control instructions to a control system. The computer system may also include data processing and analysis algorithms. The control system provides commands for a real-time processor, that may or may not be provided as a separate unit. The real-time processor may include instructions implemented as firmware to issue commands to the active device 102 and to receive data from the active device 102 at low latency. The system 100 may further include power supplies, cables, and other infrastructure. The computer system, control system, and real-time processor may be wholly or partially encompassed by the processing electronics 104 and/or DAS 106.

The system 100 may be disposed in man-made environment or natural environment; the former of which may include for example a nuclear reactor, radiation test facility, radiotherapy facility, or nuclear event, while the latter of which may include atmospheric environs (e.g., upper troposphere or stratosphere) and space. The environment may include any radiation such as photons and sub-atomic particles that can in general cause damage to electronics. In particular, radiation may include neutrons with energies ranging from thermal (approximately 40 meV) to very high energy (100 GeV).

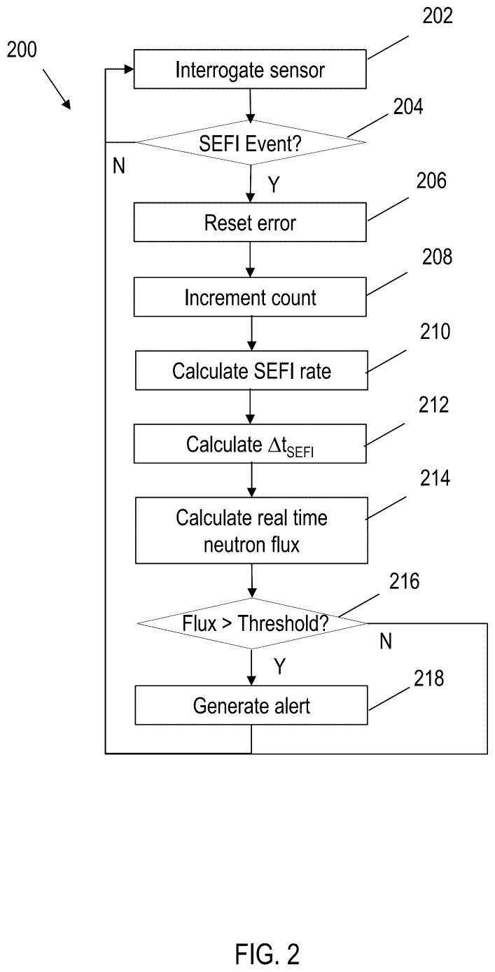

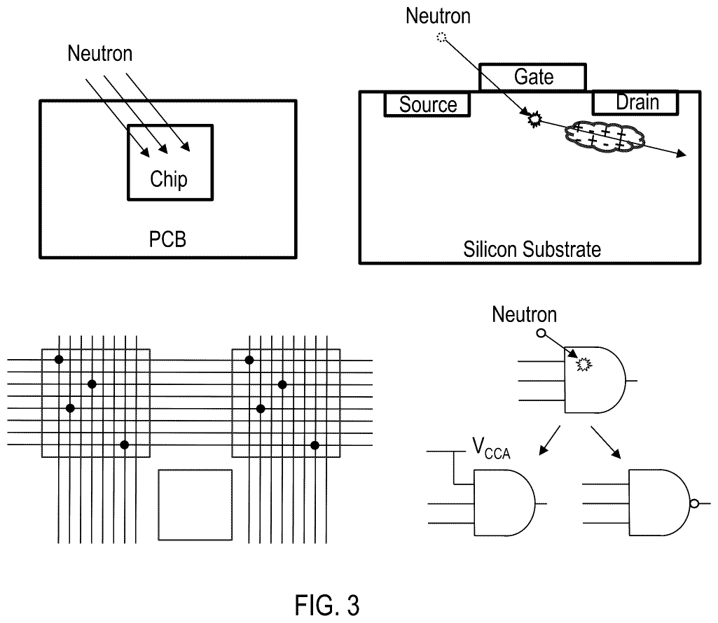

FIG. 2 shows a method of detecting events according to some embodiments. FIG. 3 illustrates graphics of the method of FIG. 2 according to some embodiments. The method 200 may have additional operations not shown. At operation 202, the real-time data acquisition system 106 may continuously interrogate the active neutron sensor device after booting the active neutron sensor device with firmware and configuration data and initializing the active neutron sensor device. The real-time data acquisition system 106 may interrogate the active neutron sensor device by sending a continuous query request to detect functional interrupts, with testing demonstrated at megahertz speeds. The active neutron sensor device may respond with its status and sample data. The functional interrupts may be caused when neutrons interact with silicon structure, as shown in the left illustration in FIG. 3. The secondary byproducts of the interactions generate charge near active junctions. This is shown in the top right illustration in FIG. 3, in which a neutron collides with a silicon atom near the depletion region of one of the terminals in a metal-oxide-semiconductor (MOSFET) of the active device. The collision may cause heavy ions to be ejected (secondary ionizing particles) and deposit ionization charges in the depletion region. The current created by the moving charge may be detected at operation 204 as a SEFI event and be interpreted as signals causing functional errors.

The charge created as a result of the nSEE may be detectable as under normal operating conditions the current between the source and drain is controlled by the gate, which creates a channel but is not active when the secondary ionizing particle current occurs. Because state-of-the-art, highly scaled integrated circuit devices have small feature sizes (for example, currently gate lengths of about 3 nm are found in many devices), even a small amount of spurious electronic charges can cause malfunction. For example, as little as a fraction of a pico-Coulomb of charge deposited by a neutron can change the state of the MOSFET, causing the logic circuit containing the MOSFET to malfunction. The results of a nSEE may be recoverable “soft” errors (SEFIs) or destructive “hard” errors. SEFIs may cause the control circuitry to hang or be unable to process data. As shown in the lower right of FIG. 3, the nSEE may cause a misconnected signal (left image) or function change (right image) for a logic module.

If a SEFI event is detected at operation 204, the system detects errors associated with the SEFI event, records a timestamp of error occurrence, and resets the errors at operation 206 (the last by, e.g., resetting at least the affected gates of the IC via a reset command). That is, status and data sample may be deemed valid or invalid. If the response is not valid, the response is counted as a SEFI event, and the time of the event is recorded. The functional error, as shown in the bottom right illustration of FIG. 3, may be detected for example as a signal that is misconnected or a change in the function of a particular logic gate embodied by the MOSFET. The error patterns are analyzed as explained below to determine neutron flux levels.

In particular, the system increments the count at operation 208 while counting the number of SEFI events observed over pre-defined time periods. The system simultaneously measures and analyzes two independent parameters: the rate of error events (calculated as the number of SEFIs divided by time (R_{SEFI}=N_{SEFI}/T)) at operation 210 and the time between individual error events at operation 212, the latter of which follows an exponential distribution. The time between individual error events is analyzed to verify that the time follows an exponential distribution [symbol] and extract the mean-time-between-events (t_{SEFI}). The rate may be rolling, which updates every time a measurement is taken, or may reset after a predetermined number of measurements.

Using calibration parameters stored in the firmware, including the neutron SEFI cross-section value (σ_{SEFI}), the system calculates the neutron flux in real-time through one or more complementary methods at operation 214. The methods to determine the neutron flux include the SEFI event count rate (F=R_{SEFI}/σ_{SEFI}) and mean-time-between-events (F=1/(σ_{SEFI}×t_{SEFI})). One or more calibration parameter determination techniques may be used to determine the calibration parameters including the neutron SEFI cross-section value, base rate of neutron events, and/or minimum level of neutron events to trigger a response.

To calibrate the detector, neutrons are generated with known flux at a dedicated facility. For example, when deuterium and tritium undergo a fusion reaction, and neutrons of known energy are created at a pre-determined rate. Neutron generation may thus include introducing deuterium and tritium into an evacuated metal enclosure, accelerating and focusing the ionized gas molecules toward a small area on a target plate. The neutrons created in this process are emitted isotropically from this point. The neutron flux, number of neutrons emitted per unit area per unit time, is determined by dosimetry methods. The sensor under calibration is placed at a known distance from the source and exposed to neutrons. The real-time processor is located nearby for low latency measurement of the rate of SEFI events caused by nSEEs. The data set collected in this manner is further processed by a computer and analysis algorithms. The analysis generates the SEFI event rate and determines the mean-time-between SEFI events. The SEFI cross sections are determined by two independent methodologies: 1) by the ratio of the event rate to the neutron flux, and 2) by the inverse of the product of neutron flux and the mean-time-between SEFI events.

Using the neutron flux calculated via one or more of the methods, at operation 216, the system may determine whether the neutron flux has exceeded a predetermined threshold. The predetermined threshold may be determined based on the application; for example, the predetermined threshold may be a level sufficient to destroy electronic devices or to cause extensive damage to a person. After the system has determined that the neutron flux has not exceeded a predetermined threshold, the active neutron sensor device returns to operation 202.

When the system determines that the neutron flux has exceeded a predetermined threshold, the system may generate an alert and/or trigger a protection mechanism at operation 218. After the system has generated the alert and/or triggered the protection mechanism, the active neutron sensor device may be re-initialized and return to operation 202. In some embodiments, the neutron flux may be calculated on a rolling basis and may be re-initialized after the neutron flux has exceeded the predetermined threshold, or may be re-initialized after an alert has been generated based on the neutron flux exceeding the predetermined threshold.

In some embodiments, when both of the methods are used, the alert/protection mechanism may be triggered when either indicates that the predetermined threshold has been exceeded, only when both indicate that the predetermined threshold has been exceeded, or when the average of both indicate that the predetermined threshold has been exceeded. The first technique may be used to provide additional caution to neutron exposure, the second technique may be used to reduce the possible number of false alarms, and the last technique may be used as a medium version between the first two techniques.

The generation of the alert may result in one or more protection mechanisms, depending on the application and environment in which the system is incorporated. For example, when a neutron event is detected, the system may initiate a rapid shutdown sequence of some or all electronics under control of the system (or perhaps within the geographic vicinity) within milliseconds to protect the electronics from radiation damage, particularly preventing burnout that can occur from photo-current generation in biased PN junctions. The system (as well as electronics on the PCB on which the system is disposed) may then be restarted within several more milliseconds, by which time the neutron event may be over. Depending on the application, the system may be configured to remain off, to account for late arriving neutrons, until a pre-determined safe level of neutron flux is reached. The timing of when the pre-determined safe level is reached (and thus when the system is restarted) may be a predetermined amount of time, may be determined by another sensor, and/or may be based on simulations based on the rate of increase of neutron flux. The system records the above measurements (the number of SEFI events over the predetermined period and the time between SEFI events) and uses the measurements to calculate the neutron flux and determine exposure severity. For electronic systems in nuclear environments, protection mechanisms may be triggered to reduce radiation effects impact on devices and humans (e.g., lead shielding being enabled, audible/electronic mass alarms being generated), with the provision that the stored data remains intact despite control circuitry effects, and systems can restart quickly after shutdown (within milliseconds). The use of the independent measurements of the neutron flux (event count rate and mean-time-between-events) may allow for verification of the readings and increased confidence in the detection accuracy.

One of the benefits of the system is the ability to be integrated with existing electronic systems. The system, for example, is able to be integrated directly onto circuit boards and interface with existing/deployed systems. The system enables compact implementation compared to conventional neutron detectors (as the system may merely use a relatively small amount of hardware, firmware, and software) to provide real-time neutron monitoring and response.

The system may support multiple configurations for redundancy. In some cases, the system may determine neutron flux from distributed sensors (ICs) across multiple circuit boards within the environment. Alternately, or in addition, multiple detectors may be networked and combined to determine neutron events. Each detector may be associated with one or more sensor(s) and may be used to determine neutron flux within the local area or global area. In one embodiment, the results from each detector may be combined in the same manner as the techniques for each detector for additional confidence in the detection accuracy—that is, the results from one detector may be used to trigger the response (e.g., shutdown and restart) or the results from at least some of the detectors may be combined to trigger the response (using the results that indicate a neutron event at each detector or based on a majority of detectors that indicate a neutron event). If a neutron event is detected, the response may be limited to those systems local to the detector/sensors at which the event was detected or may be global, across the entire environment.

In some examples, the detection methodology may utilize different error modes beyond functional interrupts, provided the error modes demonstrate stochastic behavior, a linear response to neutron flux, reproducible cross-sections, and the capability to reset the system after errors occur. The methodology has been validated through testing at neutron source facilities up to flux levels of 108 neutrons/cm²/sec, demonstrating linear response characteristics and statistical behavior matching theoretical predictions.

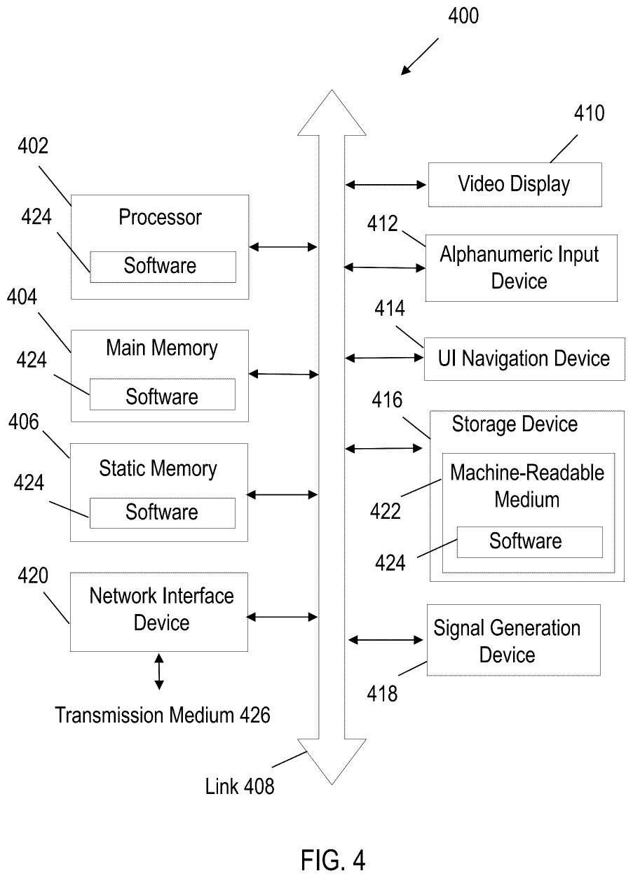

FIG. 4 illustrates a block diagram of an electronic device in accordance with some embodiments. The device 400 may be any electronic device (or circuitry) described herein. Examples of devices include specialized circuitry, a computer, a smart phone, or any machine capable of executing instructions (sequential or otherwise) that specify actions to be taken by that machine. The device 400 may include the neutron detector and/or sensors described herein.

Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The device 400 may include some or all the elements shown in FIG. 4, including a hardware processor (or equivalently processing circuitry) 402 (e.g., a central processing unit (CPU), a GPU, a hardware processor core, or any combination thereof), a main memory 404 and a static memory 406, some or all of which may communicate with each other via an interlink (e.g., bus) 408. The main memory 404 may contain any or all of removable storage and non-removable storage, volatile memory or non-volatile memory. The device 400 may further include a display unit 410 such as a video display, an alphanumeric input device 412 (e.g., a keyboard), and a user interface (UI) navigation device 414 (e.g., a mouse). In an example, the display unit 410, input device 412 and UI navigation device 414 may be a touch screen display. The device 400 may additionally include a storage device (e.g., drive unit) 416, a signal generation device 418 (e.g., a speaker), a network interface device 420, and one or more sensors, such as a global positioning system (GPS) sensor, compass, accelerometer, or another sensor. The device 400 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 416 may include a non-transitory machine readable medium 422 (hereinafter simply referred to as machine readable medium) on which is stored one or more sets of data structures or instructions 424 (e.g., software) embodying or utilized by any one or more of the techniques or functions described herein. The non-transitory machine readable medium 422 is a tangible medium. The instructions 424 may also reside, completely or at least partially, within the main memory 404, within static memory 406, and/or within the hardware processor 402 during execution thereof by the device 400. While the machine readable medium 422 is illustrated as a single medium, the term “machine readable medium” may include a single medium or multiple media (e.g., a centralized or distributed database, and/or associated caches and servers) configured to store the one or more instructions 424.

The term “machine readable medium” may include any medium that is capable of storing, encoding, or carrying instructions for execution by the device 400 and that cause the device 400 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 424 may further be transmitted or received over a communications network using a transmission medium 426 via the network interface device 420 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as IEEE 802.11 family of standards known as Wi-Fi, IEEE 802.16 family of standards known as WiMax, IEEE 802.15.4 family of standards, an LTE family of standards, a UMTS family of standards, peer-to-peer (P2P) networks, a 5G standards among others. In an example, the network interface device 420 may include one or more physical jacks (e.g., Ethernet, coaxial, or phone jacks) or one or more antennas to connect to the transmission medium 426.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

Any of the radio links described herein may operate according to any one or more of radio communication technologies and/or standards. Aspects described herein may be used in the context of any spectrum management scheme including dedicated licensed spectrum, unlicensed spectrum, license exempt spectrum, (licensed) shared spectrum and further frequencies.

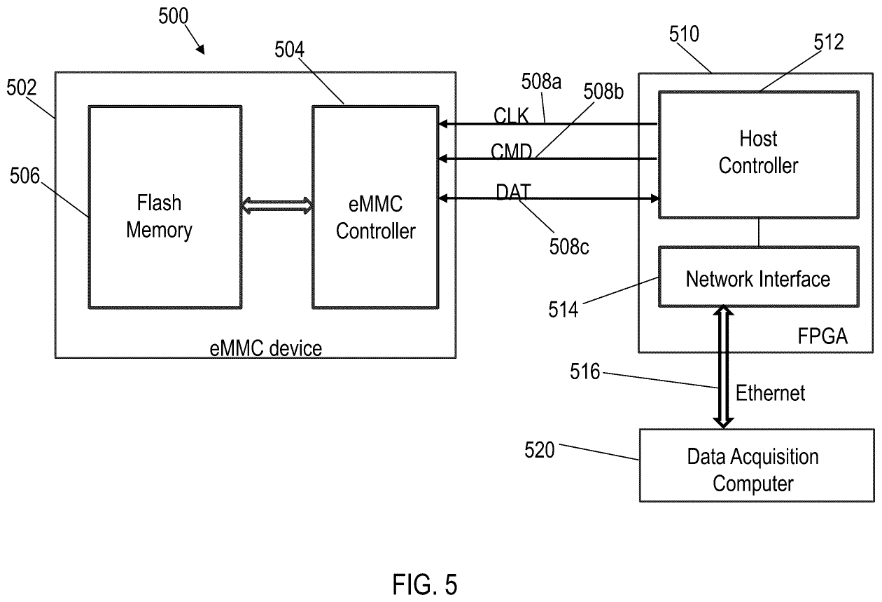

FIG. 5 illustrates another embodiment of a neutron event detection system. The system 500 may include a commercially available Embedded Multimedia Card (eMMC) device 502. The eMMC device 502 includes an eMMC controller 504 and a memory 506 that contains floating-gate (flash) type storage cells. The eMMC device 502 may be coupled to a Field Programmable Gate Array (FPGA) device 510. The FPGA device 510 may contain a host controller 512 that includes a real-time processor. The controller circuitry of the host controller 512 may provide a clock signal 508a, commands 508b, and configuration data 508c. The clock signal 508a may be used to synchronize the FPGA device 510 with the eMMC device 502. The commands 508b and configuration data 508c may be used to initialize the eMMC device and to receive data from the eMMC device 502. The FPGA device 510 may further include network interface circuitry 514 that enables communication with a remote data acquisition computer 520 via long haul Ethernet 516 cables (or other wired or wireless connections).

### EXAMPLES

Example 1 is a neutron event rate detector (NERD) system, the system comprising: an integrated circuit (IC) device configured to detect functional error modes in the IC device caused by neutron single event effects; a real-time data acquisition system coupled to the IC device to collect and monitor error data of the IC device; and a processor coupled to the IC device and the real-time data acquisition system configured to: detect functional errors in the IC device caused by neutron single event effects; determine at least one of a rate of error events based on a number of the functional errors detected over a predefined time period or a time between the error events; and calculate neutron flux using calibration parameters and the at least one of the rate of error events and time between error events.

In Example 2, the subject matter of Example 1 includes, wherein: the IC device is a commercial IC device that comprises at least one of: a microcontroller, a Field Programmable Gate Array (FPGA), or an embedded Multi-Media Card (eMMC) NAND memory device, and the processor is configured to reset gates of the commercial IC device after detection of the functional errors.

In Example 3, the subject matter of Examples 1-2 includes, wherein the processor is configured to trigger a protection mechanism to reduce an impact of radiation effects in response to detected neutron flux exceeding a predetermined threshold.

In Example 4, the subject matter of Example 3 includes, wherein the neutron event rate detector system is disposed on a printed circuit board (PCB), and the protection mechanism comprises shutting down and restarting electronics on the PCB.

In Example 5, the subject matter of Examples 1-4 includes, wherein the functional error modes comprise single event functional interrupts (SEFIs) in controller circuitry of the IC device and the calibration parameters include a neutron SEFI cross-section value.

In Example 6, the subject matter of Example 5 includes, wherein the processor is configured to determine the rate of error events and the time between events and calculate the neutron flux using the rate of error events and the time between error events.

In Example 7, the subject matter of Example 6 includes, wherein the processor is configured to provide multiple independent measurements of neutron flux including: neutron event count rate determined as a number of SEFIs divided by time, and mean-time-between-events, extracted from an exponent of a distribution of the time between error events.

In Example 8, the subject matter of Example 7 includes, wherein the processor is configured to interface with multiple IC devices simultaneously disposed on different printed circuit boards based on the independent measurements detected from each IC device to provide redundancy and increased sensitivity.

In Example 9, the subject matter of Examples 7-8 includes, wherein the processor is configured to trigger a protection mechanism to reduce impact of radiation effects in response to the neutron flux exceeding a predetermined threshold, the protection mechanism triggered in response to both independent measurements indicating that the predetermined threshold has been exceeded.

In Example 10, the subject matter of Examples 7-9 includes, wherein the processor is configured to trigger a protection mechanism to reduce impact of radiation effects in response to the neutron flux exceeding a predetermined threshold, the protection mechanism triggered in response to an average of both independent measurements indicating that the predetermined threshold has been exceeded.

Example 11 is a method for detecting neutron events, the method comprising: continuously interrogating a programmable integrated circuit (IC) device for functional error modes caused by neutron single event effects; detecting functional errors in the IC device; determining a rate of error events based on a number of detected errors over a predefined time period; determining a time between the error events; and calculating neutron flux using calibration parameters and the rate of error events and the time between events.

In Example 12, the subject matter of Example 11 includes, initiating a shutdown of the IC device within milliseconds in response to detecting a neutron event in which the neutron flux exceeds a predetermined threshold; protecting electronic systems associated with the IC device from radiation damage during the shutdown; and restarting the electronic systems after the shutdown.

In Example 13, the subject matter of Examples 11-12 includes, calibrating the IC device by: exposing the IC device to a calibrated neutron source; measuring a neutron single event functional interrupt (SEFI) cross section using event count rate and mean-time-between-events during exposure to the calibrated neutron source; and incorporating the SEFI cross section into firmware.

In Example 14, the subject matter of Example 13 includes, wherein calculating neutron flux comprises: determining the neutron flux through event count rate as a number of SEFIs divided by time; determining the neutron flux through mean-time-between-events, extracted from an exponent of a distribution of the time between error events; and providing independent measurements for verification of the neutron flux.

In Example 15, the subject matter of Example 14 includes, simultaneously monitoring multiple IC devices to provide redundancy and increased sensitivity; determining whether each of the neutron flux through the event count rate and the mean-time-between-events exceeds a predetermined threshold; and triggering a protection mechanism to reduce impact of radiation effects in response to each of the neutron flux determined through the event count rate and the mean-time-between-events exceeding the predetermined threshold.

In Example 16, the subject matter of Examples 14-15 includes, simultaneously monitoring multiple IC devices to provide redundancy and increased sensitivity; determining whether an average of the neutron flux through the event count rate and the mean-time-between-events exceeds a predetermined threshold; and triggering a protection mechanism to reduce impact of radiation effects in response to the average of the neutron flux determined through the event count rate and the mean-time-between-events exceeding the predetermined threshold.

Example 17 is a non-transitory computer-readable storage medium that stores instructions for execution by one or more processors of an apparatus of an integrated circuit (IC) device, the instructions, when executed, cause the apparatus to: monitor the IC device for functional error modes caused by neutron single event effects; detect functional errors in the IC device; determine a rate of error events based on a number of detected errors over a predefined time period; determine a time between the error events; and calculate neutron flux using calibration parameters and the rate of error events and the time between events.

In Example 18, the subject matter of Example 17 includes, wherein the instructions, when executed, further cause the apparatus to calibrate the IC device by: measuring a neutron single event functional interrupt (SEFI) cross section using event count rate and mean-time-between-events during exposure to calibrated neutron source; and incorporating the SEFI cross section into firmware.

In Example 19, the subject matter of Example 18 includes, wherein the instructions, when executed, further cause the apparatus to calculate neutron flux by: determining the neutron flux through event count rate as a number of SEFIs divided by time; determining the neutron flux through mean-time-between-events, extracted from an exponent of a distribution of the time between error events; and providing independent measurements for verification of the neutron flux.

In Example 20, the subject matter of Example 19 includes, wherein the instructions, when executed, further cause the apparatus to: simultaneously monitor multiple IC devices to provide redundancy and increased sensitivity; determine whether each of the neutron flux through the event count rate and the mean-time-between-events exceeds a predetermined threshold; and trigger a protection mechanism to reduce impact of radiation effects in response to each of the neutron flux determined through the event count rate and the mean-time-between-events exceeding the predetermined threshold.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, the subject matter lies in less than all features of a single disclosed embodiment. Thus, the following claims are hereby incorporated into the Detailed Description, with each claim standing on its own as a separate embodiment.

What is claimed is:

1. A neutron event rate detector (NERD) system, the system comprising:
an integrated circuit (IC) device configured to detect functional error modes in the IC device caused by neutron single event effects;
a real-time data acquisition system coupled to the IC device to collect and monitor error data of the IC device; and
a processor coupled to the IC device and the real-time data acquisition system configured to:
detect functional errors in the IC device caused by neutron single event effects;
determine at least one of a rate of error events based on a number of the functional errors detected over a predefined time period or a time between the error events; and
calculate neutron flux using calibration parameters and the at least one of the rate of error events and time between error events.

2. The NERD system of claim 1 wherein:
the IC device is a commercial IC device that comprises at least one of: a microcontroller, a Field Programmable Gate Array (FPGA), or an embedded Multi-Media Card (eMMC) NAND memory device, and
the processor is configured to reset gates of the commercial IC device after detection of the functional errors.

3. The NERD system of claim 1 wherein the processor is configured to trigger a protection mechanism to reduce an impact of radiation effects in response to detected neutron flux exceeding a predetermined threshold.

4. The NERD system of claim 3 wherein the neutron event rate detector system is disposed on a printed circuit board (PCB), and the protection mechanism comprises shutting down and restarting electronics on the PCB.

5. The NERD system of claim 1 wherein the functional error modes comprise single event functional interrupts (SEFIs) in controller circuitry of the IC device and the calibration parameters include a neutron SEFI cross-section value.

6. The NERD system of claim 5 wherein the processor is configured to determine the rate of error events and the time between events and calculate the neutron flux using the rate of error events and the time between error events.

7. The NERD system of claim 6 wherein the processor is configured to provide multiple independent measurements of neutron flux including:
neutron event count rate determined as a number of SEFIs divided by time, and
mean-time-between-events, extracted from an exponent of a distribution of the time between error events.

8. The NERD system of claim 7, wherein the processor is configured to interface with multiple IC devices simultaneously disposed on different printed circuit boards based on the independent measurements detected from each IC device to provide redundancy and increased sensitivity.

9. The NERD system of claim 7, wherein the processor is configured to trigger a protection mechanism to reduce impact of radiation effects in response to the neutron flux exceeding a predetermined threshold, the protection mechanism triggered in response to both independent measurements indicating that the predetermined threshold has been exceeded.

10. The NERD system of claim 7, wherein the processor is configured to trigger a protection mechanism to reduce impact of radiation effects in response to the neutron flux exceeding a predetermined threshold, the protection mechanism triggered in response to an average of both independent measurements indicating that the predetermined threshold has been exceeded.

11. A method for detecting neutron events, the method comprising:
continuously interrogating a programmable integrated circuit (IC) device for functional error modes caused by neutron single event effects;
detecting functional errors in the IC device;
determining a rate of error events based on a number of detected errors over a predefined time period;
determining a time between the error events; and
calculating neutron flux using calibration parameters and the rate of error events and the time between events.

12. The method of claim 11, further comprising:
initiating a shutdown of the IC device within milliseconds in response to detecting a neutron event in which the neutron flux exceeds a predetermined threshold;
protecting electronic systems associated with the IC device from radiation damage during the shutdown; and
restarting the electronic systems after the shutdown.

13. The method of claim 11, further comprising calibrating the IC device by:
exposing the IC device to a calibrated neutron source;
measuring a neutron single event functional interrupt (SEFI) cross section using event count rate and mean-time-between-events during exposure to the calibrated neutron source; and
incorporating the SEFI cross section into firmware.

14. The method of claim 13, wherein calculating neutron flux comprises:
determining the neutron flux through event count rate as a number of SEFIs divided by time;
determining the neutron flux through mean-time-between-events, extracted from an exponent of a distribution of the time between error events; and
providing independent measurements for verification of the neutron flux.

15. The method of claim 14, further comprising:
simultaneously monitoring multiple IC devices to provide redundancy and increased sensitivity;
determining whether each of the neutron flux through the event count rate and the mean-time-between-events exceeds a predetermined threshold; and
triggering a protection mechanism to reduce impact of radiation effects in response to each of the neutron flux determined through the event count rate and the mean-time-between-events exceeding the predetermined threshold.

16. The method of claim 14, further comprising:
simultaneously monitoring multiple IC devices to provide redundancy and increased sensitivity;
determining whether an average of the neutron flux through the event count rate and the mean-time-between-events exceeds a predetermined threshold; and
triggering a protection mechanism to reduce impact of radiation effects in response to the average of the neutron flux determined through the event count rate and the mean-time-between-events exceeding the predetermined threshold.

17. A non-transitory computer-readable storage medium that stores instructions for execution by one or more processors of an apparatus of an integrated circuit (IC) device, the instructions, when executed, cause the apparatus to:
monitor the IC device for functional error modes caused by neutron single event effects;
detect functional errors in the IC device;
determine a rate of error events based on a number of detected errors over a predefined time period;
determine a time between the error events; and
calculate neutron flux using calibration parameters and the rate of error events and the time between events.

18. The non-transitory computer-readable storage medium of claim 17, wherein the instructions, when executed, further cause the apparatus to calibrate the IC device by:
measuring a neutron single event functional interrupt (SEFI) cross section using event count rate and mean-time-between-events during exposure to calibrated neutron source; and
incorporating the SEFI cross section into firmware.

19. The non-transitory computer-readable storage medium of claim 18, wherein the instructions, when executed, further cause the apparatus to calculate neutron flux by:
determining the neutron flux through event count rate as a number of SEFIs divided by time;
determining the neutron flux through mean-time-between-events, extracted from an exponent of a distribution of the time between error events; and
providing independent measurements for verification of the neutron flux.

20. The non-transitory computer-readable storage medium of claim 19, wherein the instructions, when executed, further cause the apparatus to:
simultaneously monitor multiple IC devices to provide redundancy and increased sensitivity;
determine whether each of the neutron flux through the event count rate and the mean-time-between-events exceeds a predetermined threshold; and
trigger a protection mechanism to reduce impact of radiation effects in response to each of the neutron flux determined through the event count rate and the mean-time-between-events exceeding the predetermined threshold.
